(19) United States
(12) Patent Application Publication
(10) Pub. No.: US 2002/0096757 A1
(43) Pub. Date: Jul. 25, 2002

(54) SEMICONDUCTOR DEVICE AND METHOD OF MANUFACTURING THE SAME

(76) Inventors: YUKIHIRO TAKAO, GUNMA (JP); HIROYUKI SHINOGI, GUNMA (JP)

Correspondence Address: JOHN B PEGRAM ESQ, FISH & RICHARDSON PC, 45 ROCKEFELLER PLAZA, NEW YORK, NY, 10111

(21) Appl. No.: 09/457,184

(22) Filed: Dec. 8, 1999

(30) Foreign Application Priority Data
Dec. 10, 1998 (JP) PHEI10-351785

(51) Int. Cl. H01L 23/48; H01L 23/52

(52) U.S. Cl. 257/690

(57) ABSTRACT

In a semiconductor device inclusive of a chip size package, a plurality of slits 6A are formed in a wiring layer 6. The slits 6A each having a rectangular shape are arranged so that their longer sides are extended along the direction of extending the wiring layer 6. In this configuration, the stress to be exerted on the wiring layer can be relaxed, thereby preventing the characteristic of the underlying transistor from being deteriorated.

### BACKGROUND OF THE INVENTION

1. Field of the Invention

The present invention relates to a semiconductor device inclusive of a chip size package and a method of manufacturing it. The chip size package is also referred to as “CSP” which generally means a package having a size equal or slightly larger than the size of a chip. The chip size package intends to realize high-density packaging. The present invention intends to improve the reliability of the chip size package.

2. Description of the Related Art

The structures known previously in this technical field are a “BGA” (Ball Grid Array) having a plurality of solder balls arranged in plane; a “fine pitch BGA” in which the ball pitch in BGA is further reduced so that the outer shape of a package has a size approximately equal of the chip size; etc.

In recent years, a “wafer CSP” has been disclosed in “NIKKEI MICRODEVICE” August 1998, pp. 44-71. The wafer CSP is basically a CSP in which wirings and pads in an array are previously formed in a wafer process before a chip is diced. It is expected that this technique integrates the wafer process and package process to reduce the package cost greatly.

The wafer CSP is classified into two types of a sealing resin type and a re-wiring type. The sealing resin type is a structure in which the surface is covered with sealing resin as in a conventional package. Specifically, in the sealing type structure, a metal post is formed on a wiring layer of the chip surface, and the periphery of the chip is sealed by sealing resin. If a package is mounted on a printed board, stress caused by a difference in a thermal expansion coefficient between the package and printed board is concentrated to the metal post. It is known that generally, as the length of the metal post is increased, the stress is dispersed more greatly.

On the other hand, the re-wiring type is a structure in which re-wiring is made without using the sealing resin as shown in FIG. 11. In the re-wiring structure, an Al electrode, a Cu wiring layer 53 and an insulating layer 54 are stacked. A metal post 55 is formed on the wiring layer 53. A solder bump 56 is formed thereon. The wiring layer 53 is used as the re-wiring means for aligning/arranging the solder bump 53 in a prescribed array on the chip 51.

As described above, in the chip size package, generally, the Al electrode pad 52 arranged on the periphery of the LSI chip 52 and the metal post 55 arranged regularly in an array are connected to each other by means of the Cu wiring.

The linear expansion coefficient of Cu is approximately equal to that of Al (Cu:20 ppm, Al:29 ppm). However, the Young's modulus of Cu is twice as large as Al (Cu:12.98×10¹⁰, Al: 7.03×10¹⁰).

Therefore, in an environment with a temperature change for a temperature cycle test in CSP packaging, the Cu wiring as well as the metal post 55 may give great stress to an underlying transistor of an LSI so that the transistor characteristic is deteriorated.

The present invention has been accomplished in order to solve the above problem.

### SUMMARY OF THE INVENTION

An object of the present invention is to provide a reliable packaging structure which can reduce a temperature change in CSP packaging and suppress the influence on the characteristic of a semiconductor device.

The feature of the present invention resides in that a wiring layer has a plurality of slits. The plurality of slits each has a rectangular shape for example, and are arranged so that their longer sides are extended along the direction of extending the wiring layer, Thus, the stress due to the wiring layer can be effectively relaxed.

The above and other objects and features of the present invention will be more apparent from the following description taken in conjunction with the accompanying drawings.

A first aspect of the device is a semiconductor device comprising: a wiring layer pattern formed in a semiconductor substrate; an insulating layer for covering the wiring layer and having an opening; and a pillar-like terminal connected to said wiring layer pattern through the opening, wherein said wiring layer pattern has a plurality of slits.

A second aspect of the device is a semiconductor device according to the first aspect, wherein pillar-like terminal projects above a surface level of a semiconductor device

A third aspect of the device is a semiconductor device according to the first aspect, wherein said wiring layer pattern is made of Cu, connected to a metallic pad formed on a device region, and extends on said semiconductor substrate.

A fourth aspect of the device is a semiconductor device according to the first aspect, wherein said wiring pattern is connected to each of metallic pads arranged on the periphery of the semiconductor substrate and a plurality of pillar-like terminals arranged in an array form on the semiconductor device.

A fifth aspect of the device is a semiconductor device according to the first aspect, wherein said plurality of slits each has a rectangular shape, and are aligned so that their longer sides are extended along the direction of extending the wiring layer.

A sixth aspect of the device is a semiconductor device according to the first aspect, wherein said insulating film is made of polyimide resin and has a flat surface.

A seventh aspect of the device is a semiconductor device according to the first aspect, wherein said opening is wider on the side of the surface and is narrow on the side of the semiconductor substrate.

A eighth aspect of the device is a semiconductor device according to the first aspect, wherein said pillar-like terminal is a bump of a plated layer formed on the a metallic seed layer.

An ninth aspect of the device is a semiconductor device according to the eighth aspect, wherein said pillar-like terminal includes a solder ball formed on the plated layer.

A tenth aspect of the method is a method of manufacturing a semiconductor device including a wiring layer of Cu connected to a metallic pad and extended on a chip surface; an insulating layer for covering the chip surface inclusive of the wiring layer and having an opening; and a pillar-like terminal formed in the opening, which comprises the steps of: forming a device region in a surface of a semiconductor substrate; forming a wiring layer which is in contact with said device region so as to introduce an external terminal; and dicing said semiconductor substrate into a plurality of chips, wherein said step of forming the wiring layer includes a step of performing electrolytic plating after a photoresist layer is formed on a region except the region where the wiring layer is to be formed and on the regions where the slits are to be formed.

A eleventh aspect of the method is a method of semiconductor device according to the tenth aspect, wherein said step of forming the wiring layer comprises: a first lithography step of forming a first negative type photosensitive film as a first insulating film on the surface of said semiconductor substrate and forming a first opening by photolithography; and a second lithography step of forming a second negative type photosensitive film on said first photosensitive film and making a second opening so as to include the first opening by pattern light-exposure.

An twelfth aspect of the method is a method of semiconductor device according to the eleventh aspect, which further comprises : a step of forming a barrier metal in said first and second openings after the second lithography step; a third lithography step of forming a third photosensitive film on said barrier metal layer and making a third opening so as to include the second opening by pattern light-exposure; and a step of forming a conductor layer in said first to third openings to form a pillar-like terminal.

A thirteenth aspect of the method is a method of semiconductor device according to the twelfth aspect, which further comprises the step of: after having formed the pillar-like terminal, removing said third photosensitive film using said pillar-like terminal as a mask, and projecting said pillar-like terminal from the surface of the semiconductor substrate.

According to the above method, by using a 2 step opening constituted by the first opening and second opening which include the first opening, in the case of forming an opening having a large aspect ratio, the opening can be formed precisely and reliably. Therefore good and reliable wiring can be formed easily.

### BRIEF DESCRIPTION OF THE DRAWINGS

FIG. 1 is a plan view of a semiconductor device having a chip size package structure according to an embodiment of the present invention;

FIG. 2 is a partially enlarge plan view of the chip size package structure according to the embodiment of the present invention;

FIGS. 3 to 10 are sectional views for explaining a method of manufacturing a chip size package according to the present invention, respectively; and

FIG. 11 is a sectional view of a conventional chip size package.

### DESCRIPTION OF THE PREFERRED EMBODIMENTS

Now referring to the drawings, an explanation will be given of embodiments of the present invention.

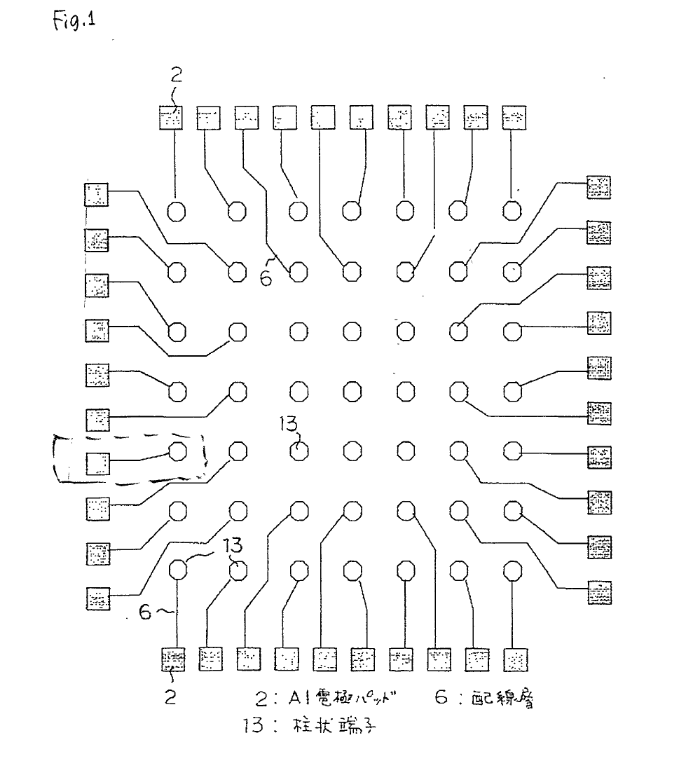

FIG. 1 is a plan view of a semiconductor device having a chip size package structure. This semiconductor device is characterized in that a plurality of slits are formed in the pattern of the a wiring layer 6 connected to a device region formed in a semiconductor substrate, thereby making heat dispersion and absorbing thermal distortion. The semiconductor is characterized in that pillar-like terminal projecting on the surface thereof is projected from an insulating layer (passivation film) covering the pattern of the wiring layer 6 through an opening.

Specifically, as seen from FIG. 1, a plurality of electrode pads 2 for an LSI are arranged on the periphery of a chip. Within an area surrounded by the Al electrode pads 2, a plurality of metal posts 13 are arranged regularly in an array. Bumps or solder balls may be located on these metal posts 13, respectively.

In order to connect these Al electrode pads 2 and the metal posts 13, wiring (re-wiring) layers 6 made of Cu are extended on the chip. Actually, as seen from FIG. 1, all the metal posts are not wired, but only necessary number of the pillar terminals can be selectively wired, and some of the metal posts 13 may not be wired. Further some of the Al electrode pads 2 may not be wired.

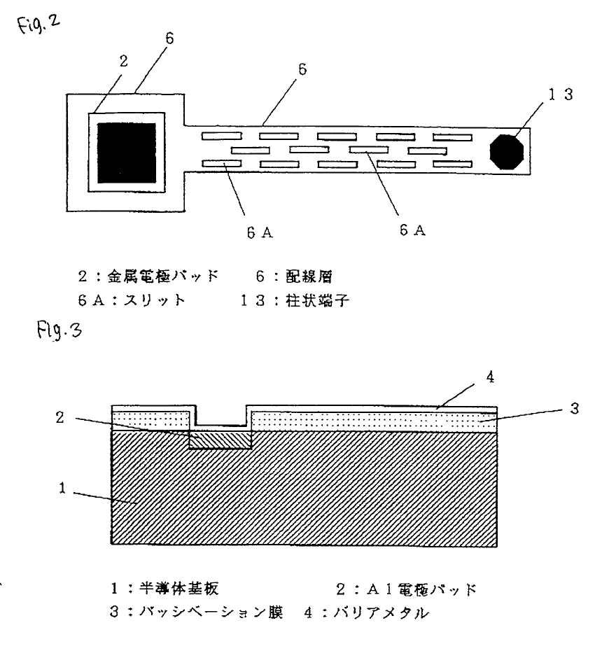

FIG. 2 is an enlarged plan view of a portion encircled by broken line in FIG. 1, i.e. a set of Al electrode pad 2, wiring layer 6 and metal post 13. The wiring layer 6 has a plurality of slits 6A.

The slits 6A each having a rectangular shape are arranged so that their longer sides are extended along the direction of extending the wiring layer 6. The slits are arranged alternately and uniformly so that the effect of relaxing the stress can be increased.

The width of the wiring layer 6 may be 50 μm-100 μm in view of a current capacity and mechanical strength. Although the size of the slit is restricted by the processing accuracy of photoresist using the electrolytic plating described later, it has a length (longer side) of 90 μm and width (shorter side) of 10 μm and an distance of about 10 μm between the adjacent slits.

Now, referring to FIGS. 3 to 10, an explanation will be given of a method of manufacturing a chip size package.

First, as shown in FIG. 3, a semiconductor substrate (wafer) 1 on which an LSI having an Al electrode pad 2 is formed is prepared. The surface of the semiconductor substrate 1 is covered with a passivation film 3 such as a SiN film.

The Al electrode pad 2 is a pad for connecting the LSI externally. The passivation film 3 on its surface is removed by etching. The entire surface of the substrate is coated with a barrier metal 4. The barrier metal 4 resides between a wiring layer which is formed later and the electrode pad 2 to protect the Al electrode pad 2. The barrier metal 2 can be formed by sputtering chrome (Cr) or titanium (Ti) etc.

Next, a wiring layer 6 which is connected to the Al electrode pad 2 will be formed. The wiring layer 6, which must have a large thickness of about 5 μm in order to assure its mechanical strength, can be conveniently formed by electrolytic plating.

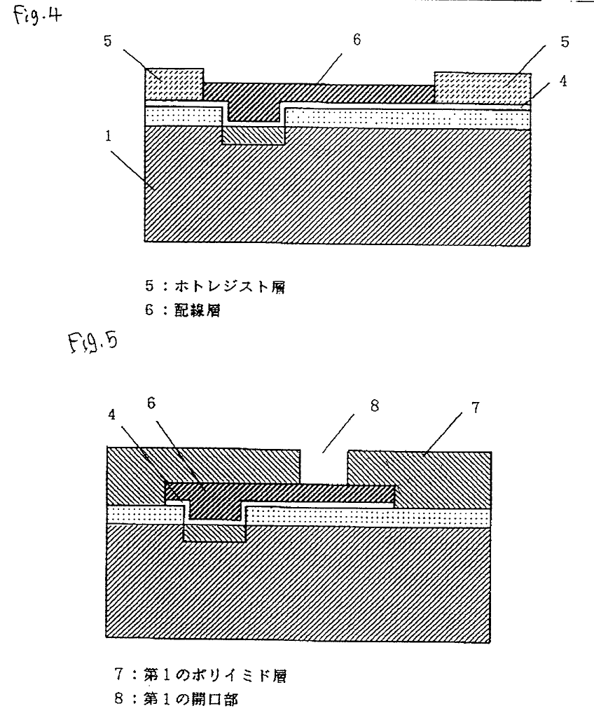

In this case, first, as seen from FIG. 4, a photoresist layer 5 is formed on the barrier metal 4 in a region except the region where the wiring layer 6 is to be formed. At the same time, the photoresist layer 5 is formed on the regions where the slits 6A are to be formed.

Using the barrier metal 4 as an electrode for plating, the wiring layer 6 plated with Cu is formed on the regions of the barrier metal 4 which are not covered with the photoresist layer 5. Thus, the wiring layer 6 is formed. The slits 6A are also simultaneously formed on the wiring layer 6.

Thereafter, the photoresist layer 5 is removed. Using the wiring layer 6 as a mask, etching is conducted to remove the unnecessary portion of the barrier metal 4.

As shown in FIG. 5, a first polyimide layer 7 is applied to the entire surface. Through light-exposure and development, a first opening 8 is formed in the first polyimide layer 7 on the wiring layer 6. The first polyimide layer 7 may be preferably made of polyimide resin doped with a photosensitive material, particularly negative type polyimide with high sensitivity. The film thickness may be 20 μm-25 μm at the maximum. The diameter of the first opening 8 may be preferably about 50 μm.

After the development, the first polyimide layer 7 is preferably baked at a temperature of about 200° C. This intends to prevent the mixing with a second polyimide layer which will be formed in a subsequent step.

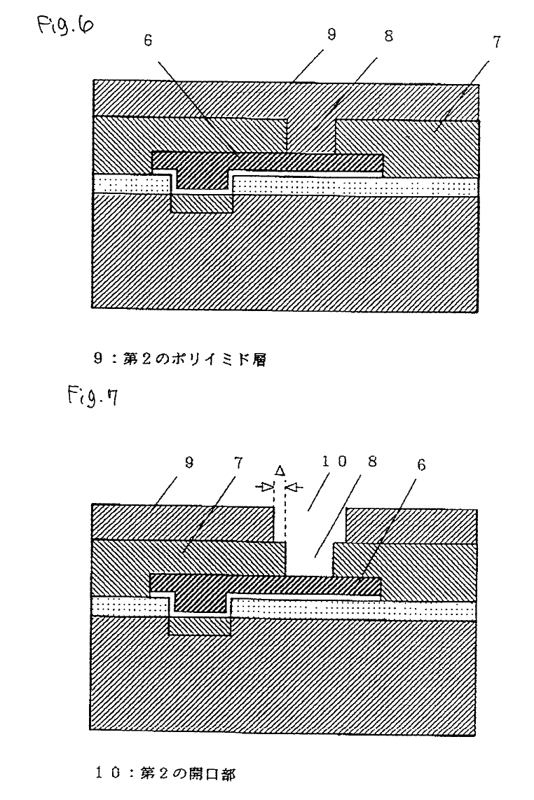

As shown in FIG. 6, a second polyimide layer 9 is applied to the entire surface. The second polyimide layer 9 is also preferably made of negative type polyimide. Its thickness is 20 μm-25 μm at its maximum like the first polyimide layer 7. The first opening 8 is filled with the second polyimide layer 9.

As shown in FIG. 7, through light-exposure and development of the second polyimide layer 9, a second opening 10 is formed on the first opening 8. The second opening 10 is located to overlap the first opening 8 horizontally so that the polyimide filled with the first opening 8 is removed. Thus, the surface of the wiring layer is exposed.

In this case, if the second polyimide layer is made of negative type polyimide, the region of the second polyimid layer exclusive of the second opening 10 is exposed to light. Therefore, after development, the second polyimide layer 9 is left at the region exposed to light, whereas the polyimide at the region corresponding to the second opening 10 is removed by the action of a developer. In this way, since the negative type polyimide is used, it is not necessary to light-expose the thick polyimide layer filled with the first opening to its bottom, but only necessary to light-expose the polyimide layer having a substantially same thickness applied to the flat surface. Therefore, the second opening 10 can be formed in the second polyimide layer 9 having a large thickness of 20 μm-25 μm.

The edge of the second opening 10 is preferably located apart from that of the first opening 8. In this case, a photomask is designed to give a horizontal distance A between these edges as shown in FIG. 7. Thus, by the light-exposure, the hardened polyimide layer can be surely formed in the entire polyimide, thereby preventing the poor resolution of the polyimide.

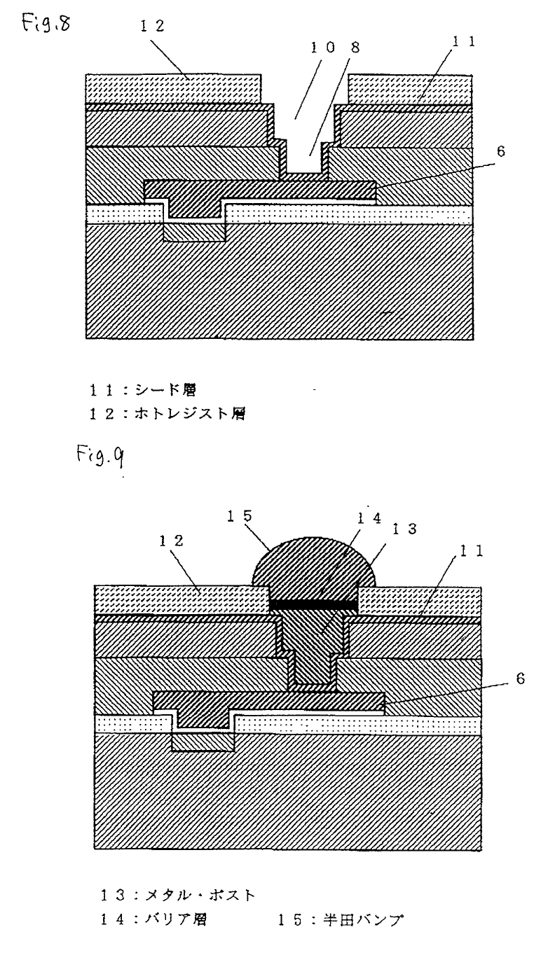

As shown in FIG. 8, a seed layer 11 for plating is formed on the entire surface inclusive of the openings 8 and 10. This seed layer, which serves as an electrode for plating, can be formed by sputtering Cu. A photoresist layer 12 is formed on the seed layer 11. By photolithography, the photoresist layer 12 is processed to provide another opening on the first and the second opening 8 and 10.

As shown in FIG. 9, by electrolytic plating, a metal post 13 serving as the pillar-like terminal, a barrier layer 14 and a solder bump 15 are formed sequentially. The barrier layer 14 is preferably a laminated film of a Pt group metal such as Au, Ni, etc. in view of the barrier characteristic of the solder bump of Pb and Sn.

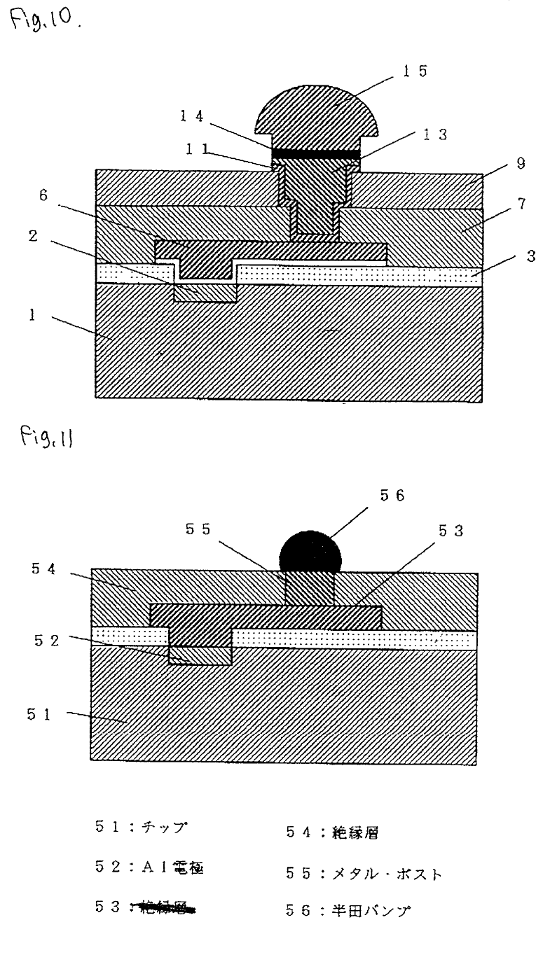

Finally, as shown in FIG. 10, the photoresist layer 12 is removed, and using the solder bump 15 as a mask, the unnecessary portion of the seed layer 11 is etched away. The semiconductor substrate 1 is divided into chips along dicing lines in a dicing step. Thus, the chip size package is completed.

By using the negative type polyimide as a material of the insulating layer for the metal post, the polyimide layer having a larger thickness of 40 μm-50 μm can be formed. Correspondingly, the metal post can be also formed to have a large depth of 40 μm-50 μm. Thus, in the chip size package not using the sealing resin, the stress exerted on the metal post can be relaxed so that the reliability of the chip size package can be improved.

As understood from the above, in a chip size package according to the present invention, a plurality of slits are formed in the wiring layer. The slits each has a rectangular shape, and they are arranged so that their longer sides are extended along the direction of extending the wiring layer. In this configuration, the stress to be exerted on the wiring layer can be relaxed, thereby preventing the characteristic of the underlying transistor from being deteriorated. Particularly, where the wiring layer is made of Cu having high thermal conductivity, the wide region occupied by the pattern of the wiring layer may produce warp of the package due to thermal stress therein. However, the semiconductor device according to the present invention, which has a plurality of slits formed in the wiring layer, provides a reliable pattern of the wiring layer which can prevent the characteristic of the underlying transistor from being deteriorated. Although the present invention is particularly effective when the wiring layer is made of Cu, the material of the wiring layer should not be limited to Cu. The wiring layer may be made of the other conductor such as aluminum.

It should be noted that the chip size package is liable to produce thermal distortion. In accordance with the present invention, this thermal distortion can be reduced because of the presence of the slits. Further, the possible warp of the wafer may lower the positioning accuracy in dicing. In accordance with the present invention, the warp can be absorbed because of the presence of the plurality of slits. This realizes the dicing with high positioning accuracy so that the reliable semiconductor device can be provided. Furthermore, in a case of mounting by using solder balls, positioning of the solder balls needs to high accuracy. However the warp of the chip may cause to lower the positioning accuracy in mounting solder balls to the chip. In accordance with the present invention, the warp can be absorbed because of the presence of the plurality of slits. This realizes the mounting the solder balls with high positioning accuracy so that the reliable semiconductor device can be provided.

The slits formed in the wiring layer in an embodiment of the present invention may be replaced by grooves which do not penetrate to reach the underlying layer.

In a method of manufacturing the chip size package according to the present invention, by electrolytic plating, the plurality of slits can be formed simultaneously when the Cu wiring layer is formed.

What is claimed is:

1. A semiconductor device comprising:
a wiring layer pattern formed in a semiconductor substrate;
an insulating layer for covering the wiring layer and having an opening; and
a pillar-like terminal connected to said wiring layer pattern through the opening, wherein
said wiring layer pattern has a plurality of slits.

2. A semiconductor device according to claim 1, wherein said pillar-like terminal projects above a surface level of a semiconductor device

3. A semiconductor device according to claim 1, wherein said wiring layer pattern is made of Cu, connected to a metallic pad formed on a device region, and extends on said semiconductor substrate.

4. A semiconductor device according to claim 1, wherein said wiring pattern is connected to each of metallic pads arranged on the periphery of the semiconductor substrate and a plurality of pillar-like terminals arranged in an array form on the semiconductor device.

5. A semiconductor device according to claim 1, wherein said plurality of slits each has a rectangular shape, and are aligned so that their longer sides are extended along the direction of extending the wiring layer.

6. A semiconductor device according to claim 1, wherein said insulating film is made of polyimide resin and has a flat surface.

7. A semiconductor device according to claim 1, wherein said opening is wider on the side of the surface and is narrow on the side of the semiconductor substrate.

8. A semiconductor device according to claim 1, wherein said pillar-like terminal is a bump of a plated layer formed on the a metallic seed layer.

9. A semiconductor device according to claim 8, wherein said pillar-like terminal includes a solder ball formed on the plated layer.

10. A method of manufacturing a semiconductor device including a wiring layer of Cu connected to a metallic pad and extended on a chip surface; an insulating layer for covering the chip surface inclusive of the wiring layer and having an opening; and a pillar-like terminal formed in the opening, comprising the steps of:
forming a device region in a surface of a semiconductor substrate;
forming a wiring layer which is in contact with said device region so as to introduce an external terminal; and
dicing said semiconductor substrate into a plurality of chips,
wherein said step of forming the wiring layer includes a step of performing electrolytic plating after a photoresist layer is formed on a region except the region where the wiring layer is to be formed and on the regions where the slits are to be formed.

11. A method of manufacturing a semiconductor device according to claim 10, wherein said step of forming the wiring layer comprises:
a first lithography step of forming a first negative type photosensitive film as a first insulating film on the surface of said semiconductor substrate and forming a first opening by photolithography; and
a second lithography step of forming a second negative type photosensitive film on said first photosensitive film and making a second opening so as to include the first opening by pattern light-exposure.

12. A method of manufacturing a semiconductor device according to claim 11, further comprising:
a step of forming a barrier metal in said first and second openings after the second lithography step;
a third lithography step of forming a third photosensitive film on said barrier metal layer and making a third opening so as to include the second opening by pattern light-exposure; and
a step of forming a conductor layer in said first to third openings to form a pillar-like terminal.

13. A method of manufacturing a semiconductor device according to claim 12, further comprising the step of:
after having formed the pillar-like terminal, removing said third photosensitive film using said pillar-like terminal as a mask, and projecting said pillar-like terminal from the surface of the semiconductor substrate.
